(19) United States
(12) Patent Application Publication
(10) Pub. No.: US 2024/0302081 A1
(43) Pub. Date: Sep. 12, 2024

(54) PRE-COOLING CIRCUIT AND METHOD FOR SUPPLYING HELIUM REFRIGERATION

(71) Applicant: Linde Kryotechnik AG, Pfungen (CH)

(72) Inventor: Lutz DECKER, Pullach (DE)

(21) Appl. No.: 18/575,596

(22) PCT Filed: Jul. 4, 2022
(86) PCT No.: PCT/EP2022/025306

§ 371 Date: Dec. 29, 2023

(30) Foreign Application Priority Data
Jul. 5, 2021 (EP) 21020348.5

(51) Int. Cl. F25B 9/14; H05K 7/20

(52) U.S. Cl. CPC F25B 9/14; H05K 7/20354

(57) ABSTRACT

A pre-cooling circuit for supplying helium refrigeration to at least one consumer to be cooled, comprising a feed line and a return line which are connected to one another via a refrigerating device, said refrigerating device being designed to exchange heat with the at least one consumer to be cooled; a helium cooling system, which is designed to dissipate heat to the environment, to compress helium flowing back and to feed the compressed helium into the feed line; a first and a second cooling bath container, the feed line running through a first heat exchanger located in a bottom region of the first cooling bath container and subsequently in the direction of the refrigerating device through a second heat exchanger located in a bottom region of the second cooling bath container.

The invention relates to a pre-cooling circuit and a method for supplying helium refrigeration for at least one consumer to be cooled.

### PRIOR ART

In basic research as well as for cooling quantum computers, cooling temperatures far below 1 K are required. For this purpose, in the present prior art, dilution cryostats are used, which are pre-cooled with pulsation tube, Sterling or Gifford-McMahon coolers down to the range from 3-4 K. A low pre-cooling temperature is a prerequisite for the efficiency of the dilution cryostat. The refrigeration capacity of these pre-cooling machines is in the range of only a few watts with additional cooling capacity at 50 K as shield cooling. Therefore, dilution cryostats are in each case equipped with 2 pulsation tube coolers, for example.

With the progress, in particular, in quantum computer research, the power requirement of pre-cooling is greatly increasing. However, the efficiency of the above-mentioned pre-cooling systems is very low. This is not particularly important for smaller applications, where the generally high purchase price of the dilution cryostat is decisive. However, if the pre-cooling systems are arranged several times, energy consumption increases linearly, so that the resulting operating costs become significant. If a plurality of dilution cryostats are additionally to be operated for, for example, a plurality of quantum computers, the problem is amplified.

Thus, there is a need for an efficient pre-cooling system which is capable of supplying one or more dilution cryostats with refrigeration, in particular helium refrigeration, with temperatures as low as possible, wherein the refrigeration supply or refrigeration capacity should be variable, in particular, in the case of a plurality of dilution cryostats.

### DISCLOSURE OF THE INVENTION

This object is achieved by a pre-cooling circuit and a method for supplying helium refrigeration for at least one consumer, having the features of the independent claims. Dependent claims relate to preferred embodiments.

The (closed) pre-cooling circuit for supplying helium refrigeration for at least one consumer to be cooled comprises a feed line and a return line, which are connected to one another via a refrigerating device, wherein the refrigerating device is designed to exchange heat with the at least one consumer to be cooled; a helium cooling system, which is designed to dissipate heat to the environment, to compress returning helium, and to feed the compressed helium into the feed line; a first and a second cooling bath container, wherein the feed line runs through a first heat exchanger located in a bottom region of the first cooling bath container and subsequently in the direction of the refrigerating device through a second heat exchanger located in a bottom region of the second cooling bath container, and wherein a top region of the first cooling bath container is connected via a recirculation line to the helium cooling system to supply it with the returning helium; and an ejector with a drive flow opening, an intake opening and an ejection opening, wherein the drive flow opening is connected to the return line, the intake opening is connected to a top region of the second cooling bath container, and the ejection opening is connected to the top region of the first cooling bath container, wherein the ejector is designed to use helium returning from the refrigerating device through the return line as a drive flow to draw in helium vapor from the second cooling bath container and to raise it to the pressure of the first cooling bath container. The term “bottom region” is also known as “sump space.”

A pre-cooling circuit according to the invention makes it possible to feed the helium compressed by the compression system to the consumer in a supercritical state, so that the occurrence of a two-phase mixture (gaseous and liquid helium), which is difficult to control, is avoided. The helium still has a sufficient pressure after passing through the consumer to raise the helium vapor of the second cooling bath container to the pressure of the first cooling bath container by means of the ejector. Overall, the use of a multistage bath cooling is thus made possible, so that a low temperature can be achieved.

The at least one consumer to be cooled is preferably a dilution cryostat.

Preferably, a secondary return line is provided, which is branched off from the return line downstream of the consumer, runs through a fourth heat exchanger arranged in the bottom region of the first cooling bath container, and opens into the return line upstream of the drive flow opening of the ejector, wherein further preferably at least one valve is arranged in the secondary return line and/or in the return line parallel to the secondary return line for controlling the flow rate through the secondary return line. This allows partial consumer operation of the pre-cooling circuit, so that, in particular, a variable number of consumers can be supplied with refrigeration.

The pre-cooling circuit preferably comprises a third cooling bath container, wherein, downstream of the second cooling bath container, the feed line runs through a third heat exchanger arranged in a bottom region of the third cooling bath container, and wherein a top region of the third cooling bath container is connected to a vacuum pump, which is designed to pump helium vapor out of the top region and feed it to the helium cooling system, wherein a compressor is preferably provided, which raises a pressure level of the pumped-out helium to a pressure level of the helium cooling system. This makes it possible to achieve a lower temperature.

The first cooling bath container is preferably designed to receive liquid helium in the bottom region, which liquid helium is in equilibrium with helium vapor in the top region, wherein an equilibrium pressure is in the range from 1.0 bar to 1.5 bar, and the second cooling bath container is designed to receive liquid helium in the bottom region, which liquid helium is in equilibrium with helium vapor in the top region, wherein a second equilibrium pressure is preferably in the range from 0.4 bar to 0.65 bar, and, optionally, the third cooling bath container is designed to receive liquid helium in the bottom region, which liquid helium is in equilibrium with helium vapor in the top region, wherein a third equilibrium pressure is preferably in the range from 0.1 bar to 0.3 bar. In the two-stage case, temperatures less than or equal to 3.6 K can thus be achieved. In the three-stage case, temperatures less than 3 K can thus be achieved.

The helium cooling system preferably comprises at least one compressor and is designed to compress helium to a pressure in the range from 7 bar to 18 bar, preferably in the range from 10 bar to 15 bar. The high pressure prevents the formation of a two-phase helium mixture.

The helium cooling system preferably comprises a heat exchanger system, wherein the returning helium is fed through the heat exchanger system in counterflow to the compressed helium.

Furthermore, the refrigerating device preferably comprises a shield circuit; and the helium cooling system is designed to provide a helium shield flow, wherein the helium shield flow is fed from the helium cooling system to the shield circuit and is fed from the latter back to the helium cooling system. An outer shield cooling of the consumer can thereby be supplied.

The refrigerating device is preferably designed to exchange heat with a plurality of consumers to be cooled, wherein the consumers can be connected and disconnected independently of one another to the feed line and the return line. It is thus possible to vary the number of consumers.

A cryogenic system according to the invention comprises a (closed) pre-cooling circuit according to the invention and at least one dilution cryostat, which is connected to the refrigerating device as the at least one consumer to be cooled, wherein the refrigerating device is preferably designed so that the feed line and the return line are connected to at least one helium bath of the at least one dilution cryostat.

In a cryogenic method according to the invention, at least one sample is placed in the at least one dilution cryostat of a cryogenic system according to the invention and cooled to a temperature below 1 K.

The method according to the invention for supplying helium refrigeration for at least one consumer to be cooled comprises compressing returning helium; leading the compressed helium through a first cooling bath and a subsequent second cooling bath to obtain helium in a supercritical state; feeding the supercritical helium to a refrigerating device, which is in heat exchange with the at least one consumer to be cooled; feeding a return flow of helium from the refrigerating device to a drive flow opening of an ejector; drawing in a second helium vapor, which is in equilibrium with the second cooling bath by means of the ejector and supplying to the first helium vapor, which is in equilibrium with the first cooling bath, and dissipating the first helium vapor to obtain the returning helium.

Preferably, the method further comprises branching off at least a portion of the return flow to form a secondary return flow, feeding the secondary return flow through the first cooling bath and subsequently into the return flow.

Preferably, the method comprises leading the compressed helium through a third cooling bath downstream of the second cooling bath.

For the sake of simplicity, this application refers to “supplying refrigeration” or a “refrigeration output” by the pre-cooling circuit, or to the fact that “a consumer is supplied with refrigeration” or that “refrigeration is delivered to a consumer.” This is to be understood in each case in the sense that heat is absorbed or removed from the consumer by the pre-cooling circuit (by means of a corresponding heat exchange device).

The term “line” or “fed” refers to lines for fluids, in particular helium, which is preferably gaseous. This means pipes or pipelines. Likewise, the term “connected” refers to the fact that a fluidic connection exists via a (pipe) line. In all cases, valves can be provided, which influence or control the fluid flow through the line.

The invention is explained in more detail hereafter with reference to the accompanying drawings, which illustrate the present invention and its features in comparison to the prior art.

### BRIEF DESCRIPTION OF THE DRAWINGS

FIG. 1 shows a pre-cooling circuit with two-stage bath cooling according to a preferred embodiment of the invention;

FIG. 2 shows a pre-cooling circuit with variably designed two-stage bath cooling according to another preferred embodiment of the invention;

FIG. 3 shows a pre-cooling circuit with three-stage bath cooling according to a further preferred embodiment of the invention;

FIG. 4 shows a pre-cooling circuit with variably designed three-stage bath cooling according to a further preferred embodiment of the invention;

FIG. 5 shows a refrigerating device, which is connected to consumers to be cooled, in particular a dilution cryostat; and

FIG. 6 shows the method according to the invention according to a preferred embodiment.

### EMBODIMENT(S) OF THE INVENTION

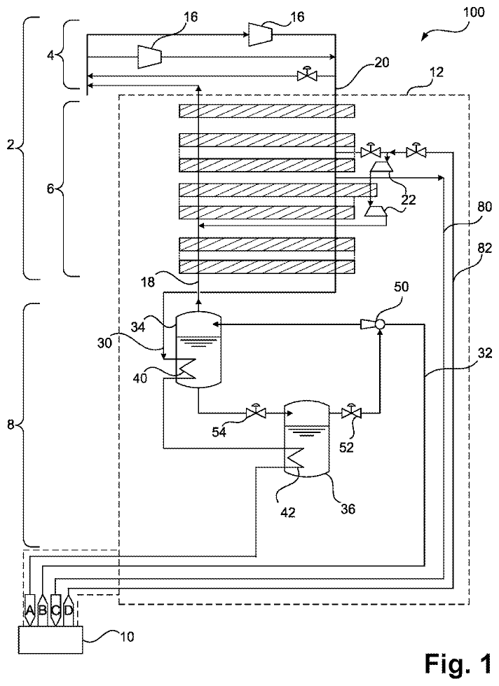

FIG. 1 shows a pre-cooling circuit 100 with two-stage bath cooling according to a preferred embodiment of the invention. The pre-cooling circuit comprises a helium cooling system 2, which includes a compressor system 4 and a heat exchanger system 6, and a bath cooling system 8, which includes a first cooling bath container 34 and a second cooling bath container 36. Together with a refrigerating device 10, which is designed for heat exchange with at least one consumer to be cooled, a closed pre-cooling circuit (for the consumer to be cooled further) is formed, wherein helium is used as cooling medium.

The compressor system 4 comprises at least one compressor 16, which compresses helium flowing back through a recirculation line 18. A pressure of the returning helium typically is at about 1.05 bar. A pressure of the compressed helium is typically in the range from 7 to 18 bar, preferably in the range from 10 to 15 bar. Furthermore, a heat dissipating device (not shown) can be provided in or on the compressor system, via which heat dissipating device heat can be dissipated to the environment.

The compressed helium is fed via a supply line 20 to a feed line 30. The recirculation line 18 and the supply line 20 run through the heat exchanger system 6, so that a heat exchange is made possible in counterflow between the returning helium and the compressed helium.

Furthermore, one or more turbines 22 can be provided in the refrigeration system 2, via which turbines compressed helium, which is removed from the supply line at a location in the heat exchanger system 6, is expanded to the pressure level of the supply line, and is fed back to the returning helium in the recirculation line at a (possibly different) location in the heat exchanger system, so that in principle a Brayton cycle is formed.

The feed line 30 running through the bath cooling system 8 initially runs through a first heat exchanger 40 arranged in a bottom region of the first cooling bath container 34 and then through a second heat exchanger 42 arranged in a bottom region of the second cooling bath container 36. The cooling bath containers are in each case designed so that there is a helium bath, i.e., helium in the liquid state, in the bottom region and helium vapor is in the top region, which is in equilibrium with the liquid helium in the bottom region. A corresponding temperature can thus be assigned to a pressure, i.e., an equilibrium pressure, in the cooling bath container (corresponding to the vapor pressure curve). In the first cooling bath container 34, the pressure is preferably approximately 1.25 bar, i.e., is in the range from 1.0 bar to 1.5 bar. In the second cooling bath container 36, the pressure is preferably approximately 0.5 bar, i.e., is in the range from 0.4 bar to 0.65 bar. The bottom region of the first cooling bath container 34 is connected via a line to the second cooling bath container 36 or its top region to be able to supply helium to the latter, wherein a valve 54 is provided in the line to be able to control this supply of helium.

Overall, a temperature of the helium fed to the refrigerating device 10 can be lowered to 3.6 K or less by means of the two-stage bath cooling (in the first and second cooling bath containers 34, 36).

After the helium has been supplied to the refrigerating device 10 via the feed line 30 and was used by the refrigerating device for cooling the at least one consumer, the helium is fed from the refrigerating device into the return line 32.

The return line 32 is connected to an ejector 50, so that helium returned by the return line from the refrigerating device can be used as a drive flow in the ejector in order to suck in helium vapor from the second cooling bath container 36 and to raise it to the pressure of the first cooling bath container 34 and eject it into the same. Accordingly, a drive flow opening of the ejector is connected to the return line, an intake opening of the ejector is connected to the top region of the second cooling bath container (via a line) and an ejection opening of the ejector is connected to the top region of the first cooling bath container (via a line). A further liquefaction of the helium can in this way be avoided in the pre-cooling circuit. A valve 52 is preferably provided in the connection line between the top region of the second cooling bath container 36 and the ejector 50 or its suction opening to be able to control the vapor flow from the top region of the second cooling bath container to the ejector.

The top region of the first cooling bath container 34 is connected to the recirculation line 20 of the refrigeration system 2, so that the helium circuit is closed.

Furthermore, it can be provided to provide a shield cooling flow, which can be used by the consumer for external cooling. For this purpose, for example, a shield flow feed line 80 and a shield flow return line 82 are provided, wherein compressed helium removed from the heat exchanger system 6 or the supply line 18 is fed to the consumer via the shield flow feed line 80, and the helium is fed back into the heat exchanger system 6 via the shield flow return line 82, for example via the turbines 22.

With the exception of the compressor system 4, the elements of the pre-cooling circuit are preferably arranged in a cold box 12, i.e., surrounded by heat-insulating walls. Likewise, the lines to and from the refrigerating device 10 are surrounded by heat-insulating walls. Indicated in each case with dashed lines.

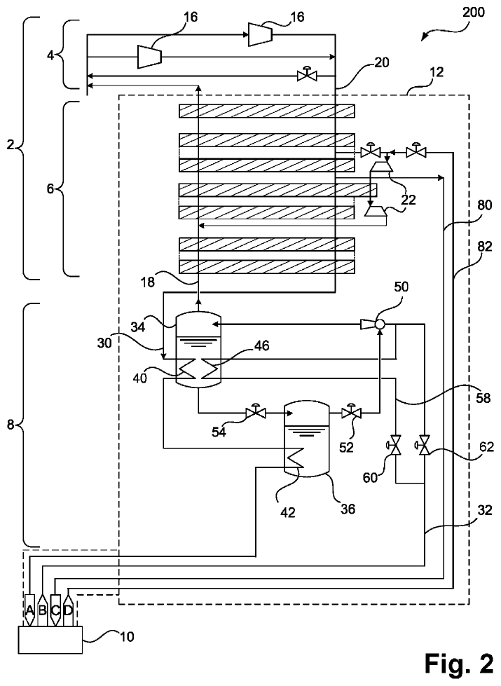

FIG. 2 shows a pre-cooling circuit 200 with a variably designed two-stage bath cooling according to another preferred embodiment of the invention. This embodiment largely corresponds to the embodiment shown in FIG. 1. In the following, therefore, essentially only different or additional elements will be discussed and elements that have already been explained in connection with FIG. 1 will not be explained again.

In contrast to FIG. 1, a secondary return line 58 is additionally provided here. The secondary return line is connected to a branch of the return line 32, so that helium coming from the refrigerating device 10 can be partially diverted or branched off from the return line. Valves 60, 62 are provided in the secondary return line and the return line to be able to control the helium flows into the secondary return line or the return line.

The secondary return line 58 passes through a fourth heat exchanger 46 arranged in the bottom region of the first cooling bath container 34 and is subsequently brought together again with the return line 32, upstream of the ejector 50. By cooling the portion of the helium fed through the secondary return line, the temperature at the drive flow opening of the ejector can be influenced, which allows an adjustment (indirectly, by means of the valves 60, 62 in the secondary return line or return line) of the operating point of the ejector 50. The pre-cooling circuit can thus be used with different consumers, since the helium flow is substantially determined by the operating point of the ejector. For example, different numbers of consumers to be cooled can be supplied with refrigeration via the refrigerating device 10.

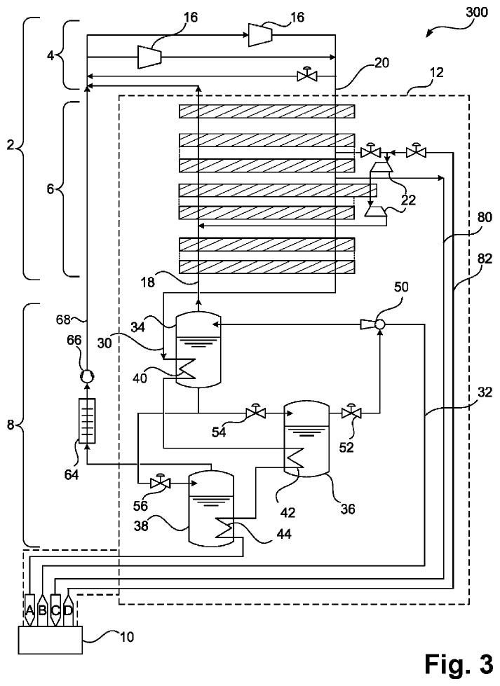

FIG. 3 shows a pre-cooling circuit 300 with three-stage bath cooling according to a further preferred embodiment of the invention. This embodiment largely corresponds to the embodiment shown in FIG. 1. In the following, therefore, essentially only different or additional elements will be discussed and elements that have already been explained in connection with FIG. 1 will not be explained again.

This embodiment additionally comprises a third cooling bath container 38, wherein the feed line 32 is passed through a third heat exchanger 44 arranged in a bottom region of the third cooling bath container 38 downstream of the second cooling bath container 36. In the third cooling bath container 38, an equilibrium between liquid helium in the bottom region and helium vapor in the top region is again present. The pressure is preferably approximately 0.2 bar, i.e., is in the range from 0.1 bar to 0.3 bar. In this way, a further temperature decrease of the helium fed by the feed line of the refrigerating device can be achieved. For example, a temperature below 3 K can be achieved.

A vacuum pump 64 is connected via a line to a top region of the third cooling bath container 38 and is designed to pump helium vapor out of the top region. The pumped-out helium is fed via a line 68, in which a compressor 66 is arranged, into the recirculation line 18 of the refrigeration system 2. The compressor is used to raise the pressure of the helium to the level in the recirculation line.

The bottom region of the first cooling bath container 34 is connected via a line to the third cooling bath container 38 or its top region to be able to supply it with helium, wherein a valve 56 is provided in the line to be able to control this supply of helium.

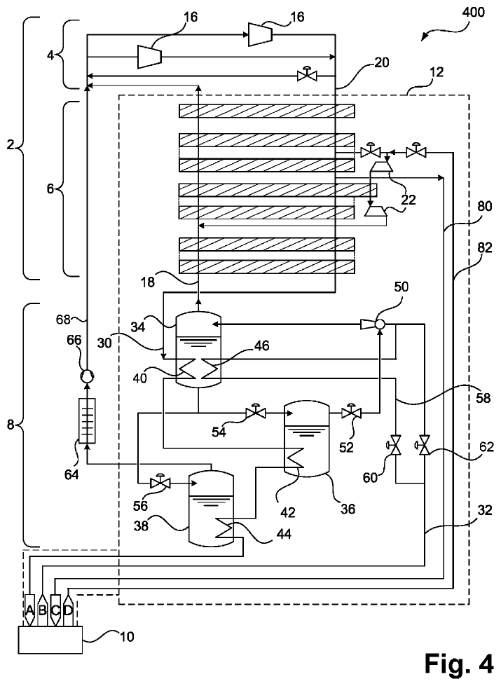

It is also possible to combine the embodiments of FIGS. 2 and 3, i.e., to additionally provide a third cooling stage, i.e., a third cooling bath container, a vacuum pump, a compressor and the corresponding lines/valves, according to FIG. 3, in the embodiment according to FIG. 2. A corresponding pre-cooling circuit 400 is shown in FIG. 4. All elements of this pre-cooling circuit have already been explained in connection with FIGS. 1 to 3.

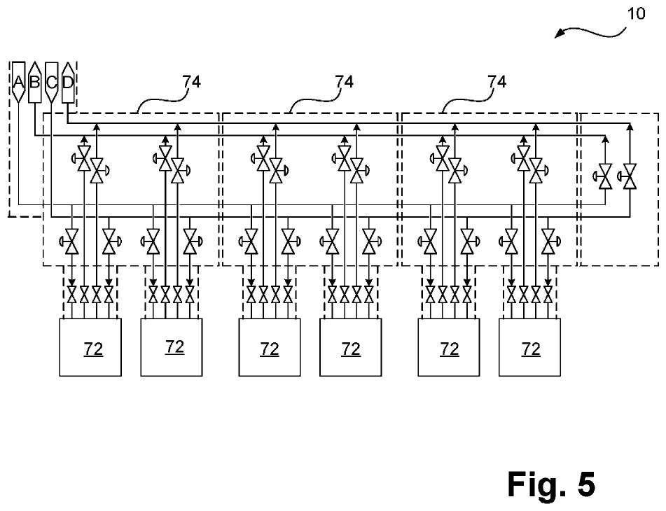

FIG. 5 shows a refrigerating device 10 which is connected to consumers 72 to be cooled, in particular dilution cryostats. This refrigerating device 10 can in particular be used for each of the embodiments corresponding to FIGS. 1, 2, 3. The assignment of the connections is indicated in the figures by arrows which are provided with the letters ‘A’, ‘B’, ‘C’ and ‘D.’

The refrigerating device 10 comprises a plurality of (here, for example, three) valve groups 74, in which, in each case, lines to individual consumers or consumer groups 72 are connected to the feed line 32 or the return line 34 are provided. These lines are provided with valves in the valve groups, so that the helium can be fed in a targeted manner from the feed line to individual consumers and can be fed from the latter into the return line. The consumers 72 can thus, independently from one another, be connected to and separated from the feed line (‘A’) and the return line (‘B’). This is particularly advantageous together with the pre-cooling circuits 200, 400 of FIGS. 2 and 4, which enable partial consumer operation.

In the valve groups 74, lines and valves are likewise provided for a shield cooling current, via which lines said shield cooling flow can be fed from the shield current feed line (‘C’) to the consumers and back to the shield current return line (‘D’). A shield circuit is thus created.

A cold box or a plurality of cold boxes is preferably again provided, within which the valve groups and preferably also consumers, in particular the dilution cryostats, are arranged.

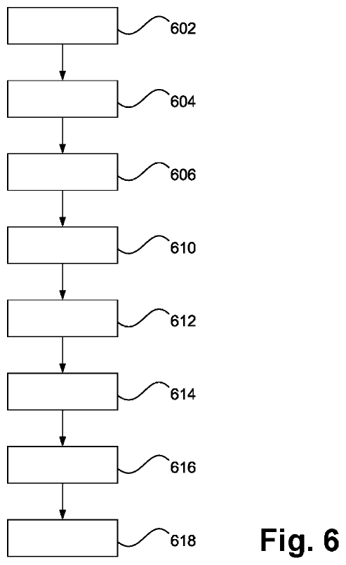

FIG. 6 shows the method according to the invention according to a preferred embodiment. The individual steps are part of a circuit which the helium passes through. In step 602, the returning helium is compressed (for example, by means of the compressor system). The pressure achieved is in the range from 7 to 18 bar, preferably from 10 to 15 bar.

In step 604, the compressed helium is fed through a first cooling bath and a subsequent second cooling bath to obtain helium in a supercritical state. In the preferred step 606, the helium is fed through a third cooling bath downstream of the second cooling bath. The cooling baths are in equilibrium with a corresponding first, second or third helium vapor. The equilibrium pressure corresponds in each case to the pressure mentioned above in connection with the first, second or third cooling bath containers.

In step 610, the supercritical helium is fed to a refrigerating device which is in heat exchange with the at least one consumer to be cooled.

In step 612, a return flow of the helium is fed from the refrigerating device to a drive flow opening of an ejector. Optionally, in step 614, at least a portion of the return flow can be branched-off to form a secondary return flow, the secondary return flow can be fed through the first cooling bath and subsequently be fed into the return flow.

In step 616, the ejector draws in the second helium vapor, which is in equilibrium with the second cooling bath, and supplies it to the first helium vapor, which is in equilibrium with the first cooling bath.

The first helium vapor is dissipated in step 618 to obtain the returning helium which is compressed in step 602 so that the circuit is completed.

1. A pre-cooling circuit for supplying helium refrigeration for at least one consumer to be cooled, comprising
a feed line and a return line, which are connected to one another via a refrigerating device, wherein the refrigerating device is designed to exchange heat with the at least one consumer to be cooled;
a helium cooling system, which is designed to dissipate heat to the environment, to compress returning helium, and to feed the compressed helium into the feed line;
a first and a second cooling bath container, wherein the feed line runs through a first heat exchanger arranged in a bottom region of the first cooling bath container and subsequently in the direction of the refrigerating device through a second heat exchanger arranged in a bottom region of the second cooling bath container, and wherein a top region of the first cooling bath container is connected to the helium cooling system via a recirculation line to supply the returning helium to said helium cooling system;
an ejector having a drive flow opening, an intake opening and an ejection opening, wherein the drive flow opening is connected to the return line, the intake opening is connected to a top region of the second cooling bath container, and the ejection opening is connected to the top region of the first cooling bath container, wherein the ejector is designed to use helium returning from the refrigerating device as a drive flow to draw in helium vapor from the second cooling bath container and to raise it to the pressure of the first cooling bath container.

2. The pre-cooling circuit according to claim 1,
wherein a secondary return line, which is branched off from the return line downstream of the consumer, runs through a fourth heat exchanger arranged in the bottom region of the first cooling bath container, and opens into the return line upstream of the drive flow opening of the ejector;
wherein preferably at least one valve is arranged in the secondary return line and/or in the return line parallel to the secondary return line for controlling the flow through the secondary return line.

3. The pre-cooling circuit according to claim 1, comprising
a third cooling bath container, wherein the feed line, downstream of the second cooling bath container, runs through a third heat exchanger arranged in a bottom region of the third cooling bath container, and wherein a top region of the third cooling bath container is connected to a vacuum pump, which is designed to pump helium vapor out of the top region and supply the helium cooling system, wherein a compressor is preferably provided, which raises a pressure level of the pumped-out helium to a pressure level of the helium cooling system.

4. The pre-cooling circuit according to claim 1,
wherein the first cooling bath container is designed to receive liquid helium in the bottom region, which is in equilibrium with helium vapor in the top region, wherein a is in the range from 1.0 bar to 1.5 bar, and
wherein the second cooling bath container is designed to receive liquid helium in the bottom region, which is in equilibrium with helium vapor in the top region, wherein a second equilibrium pressure is preferably in the range from 0.4 bar to 0.65 bar, and
wherein the third cooling bath container is designed to receive liquid helium in the bottom region, which is in equilibrium with helium vapor in the top region, wherein a third equilibrium pressure is preferably in the range from 0.1 bar to 0.3 bar.

5. The pre-cooling circuit according to claim 1,
wherein the helium cooling system comprises at least one compressor and is designed to compress helium to a pressure in the range from 7 bar to 18 bar, preferably in the range from 10 bar to 15 bar.

6. The pre-cooling circuit according to claim 5,
wherein the helium cooling system comprises a heat exchanger system, wherein the returning helium is fed through the heat exchanger system in counterflow to the compressed helium.

7. The pre-cooling circuit according to claim 1,
wherein the refrigerating device comprises a shield circuit; and
wherein the helium cooling system is designed to provide a helium shield flow, wherein the helium shield flow is fed from the helium cooling system to the shield circuit and is fed back from said shield circuit to the helium cooling system.

8. The pre-cooling circuit according to claim 1,
wherein the refrigerating device is designed to exchange heat with a plurality of consumers to be cooled, wherein the consumers can be independently of one another connected to and disconnected from the feed line and the return line.

9. A cryogenic system comprising the closed pre-cooling circuit according to claim 1 and at least one dilution cryostat, which is connected to the refrigerating device as the at least one consumer to be cooled, wherein the refrigerating device is preferably designed so that the feed line and the return line are connected to at least one helium bath of the at least one dilution cryostat.

10. A cryogenic method, wherein at least one sample is placed in the at least one dilution cryostat of a cryogenic system according to claim 9 and is cooled to a temperature below 1 K.

11. A method for supplying helium refrigeration for at least one consumer to be cooled, comprising
compressing returning helium;
leading the compressed helium through a first cooling bath and a subsequent second cooling bath to obtain helium in a supercritical state;
feeding the supercritical helium to a refrigerating device, which is in heat exchange with the at least one consumer to be cooled;
feeding a return flow of helium from the refrigerating device to a drive flow opening of an ejector;
drawing in a second helium vapor, which is in equilibrium with the second cooling bath, by means of the ejector and supplying it to a first helium vapor, which is in equilibrium with the first cooling bath;
dissipating the first helium vapor to obtain the returning helium.

12. The method according to claim 11, comprising
branching-off at least a portion of the return flow to form a secondary return flow;
leading the secondary return flow through the first cooling bath and subsequently into the return flow.

13. The method according to claim 11, comprising leading the compressed helium through a third cooling bath downstream of the second cooling bath.
